(19) United States
(12) Patent Application Publication
(10) Pub. No.: US 2023/0057872 A1
(43) Pub. Date: Feb. 23, 2023

(54) CHEMICAL MECHANICAL POLISHING (CMP) SLURRY, SEMICONDUCTOR STRUCTURE, AND MANUFACTURING METHOD OF SEMICONDUCTOR STRUCTURE

(71) Applicant: CHANGXIN MEMORY TECHNOLOGIES, INC., Hefei City (CN)

(72) Inventor: CHANG-YI TSAI, Hefei City (CN)

(21) Appl. No.: 17/656,746

(22) Filed: Mar. 28, 2022

(30) Foreign Application Priority Data
Aug. 23, 2021 (CN) 202110968068.9

(51) Int. Cl. C09G 1/02; H01L 21/306

(52) U.S. Cl. CPC C09G 1/02; H01L 21/30625

(57) ABSTRACT

Embodiments of the present disclosure relate to CMP slurry, CMP equipment, a semiconductor structure, and a manufacturing method of a semiconductor structure. The CMP slurry is configured to thin a polycrystalline silicon structure, so as to obtain a polycrystalline silicon layer with a flat surface, and includes: silicon dioxide abrasive particles, a peroxy compound, and deionized water. The peroxy compound has a volume percentage not less than 3% and not greater than 10%.

### CROSS-REFERENCE TO RELATED APPLICATION

This disclosure claims the priority of Chinese Patent Application No. 202110968068.9 submitted to the Chinese Intellectual Property Office on Aug. 23, 2021, the disclosure of which is incorporated herein in its entirety by reference.

### TECHNICAL FIELD

Embodiments of the present disclosure relate to the technical field of semiconductors, and in particular, to chemical mechanical polishing (CMP) slurry, CMP equipment, a semiconductor structure, and a manufacturing method of the semiconductor structure.

### BACKGROUND

With the development of the semiconductor industry, the size of electronic devices is gradually reduced, and the flatness of the wafer surface is required to reach the nano-level. Conventional planarization techniques can only achieve local planarization, and global planarization shall be performed when the minimum feature size is less than or equal to 0.25 microns. Common planarization techniques include a heat flux method, a spin-on-glass (SOG) method, an etch-back method, an electron spin resonance method, a selective deposition method, a low-pressure plasma-enhanced chemical vapor deposition (PECVD), and a deposition-etching-deposition method, all of which belong to the local planarization processes and cannot achieve global planarization. The CMP process is a typical global planarization process that uses a mixture of abrasives and chemicals and polishing pads to smooth wafers or other substrate materials to achieve global planarization.

In a typical polycrystalline silicon CMP process, alkaline silicon dioxide polishing slurry is used for planarization. After planarization and cleaning to remove the particles, there will be particle residuals on the surface of the polycrystalline silicon. In addition, in the process of planarization, the surface of the polycrystalline silicon will be scratched due to the mechanical force, and the particles and scratches will affect the yield of semiconductor devices.

### SUMMARY

The present disclosure provides CMP slurry, configured to thin a polycrystalline silicon structure, so as to obtain a polycrystalline silicon layer with a flat surface, and including: silicon dioxide abrasive particles, a peroxy compound, and deionized water.

The peroxy compound has a volume percentage not less than 3% and not greater than 10%.

The present disclosure provides CMP equipment, using the CMP slurry according to any one described above for CMP.

The present disclosure provides a manufacturing method of a semiconductor structure, including:

providing a polycrystalline silicon structure; and

thinning the polycrystalline silicon structure using the CMP slurry according to any one described above, so as to obtain a polycrystalline silicon layer with a flat surface.

The present disclosure provides a semiconductor structure, manufactured by the manufacturing method of a semiconductor structure according to any one described above.

### BRIEF DESCRIPTION OF THE DRAWINGS

To describe the technical solutions in the embodiments of the present disclosure or in the related art more clearly, the following briefly describes the accompanying drawings required for describing the embodiments or the related art. Apparently, the accompanying drawings in the following description show merely some embodiments of the present disclosure, and a person of ordinary skill in the art may still derive other drawings from these accompanying drawings without creative efforts.

FIG. 1 is a schematic diagram of friction between CMP slurry and a polycrystalline silicon structure and a percentage of a peroxy compound in the CMP slurry in an embodiment;

FIG. 2 is a schematic diagram of a surface of each polycrystalline silicon layer obtained by the CMP slurry with different percentages of the peroxy compound corresponding to FIG. 1;

FIG. 3 is a schematic diagram illustrating variations of a contact angle of a polycrystalline silicon structure with a percentage of hydrogen peroxide in an embodiment;

FIG. 4 is a schematic flowchart of a manufacturing method of a semiconductor structure in an embodiment;

FIG. 5 is a schematic flowchart of providing a polycrystalline silicon structure in an embodiment;

FIG. 6 is a schematic cross-sectional diagram of a semiconductor structure after a groove is formed in an embodiment;

FIG. 7 is a schematic cross-sectional diagram of a semiconductor structure after a polycrystalline silicon film layer is formed in an embodiment;

FIG. 8 is a schematic cross-sectional diagram of a semiconductor structure after thinning in an embodiment; and

FIG. 9 is a schematic cross-sectional diagram of a semiconductor structure after a polycrystalline silicon layer is formed in an embodiment.

### DETAILED DESCRIPTION

To facilitate the understanding of embodiments of the present disclosure, the embodiments of the present disclosure are described more completely below with reference to the accompanying drawings. The preferred embodiments of the present disclosure are shown in the accompanying drawings. However, the embodiments of the present disclosure may be embodied in various forms without being limited to the embodiments described herein. On the contrary, these embodiments are provided to make the embodiments of the present disclosure more thorough and comprehensive.

Unless otherwise defined, all technical and scientific terms used herein have the same meaning as commonly understood by those skilled in the technical field of the embodiments of the present disclosure. The terms used in specifications of the embodiments of the present disclosure are merely for the purpose of describing specific embodiments, rather than to limit the embodiments of the present disclosure. The term “and/or” used herein includes any and all combinations of one or more of the associated listed items.

It should be understood that in the description of the embodiments of the present disclosure, the terms such as “upper”, “lower”, “vertical”, “horizontal”, “inner” and “outer” indicate the orientation or position relationships based on the drawings. These terms are merely intended to facilitate description of the embodiments of the present disclosure and simplify the description, rather than to indicate or imply that the mentioned device or element must have a specific orientation and must be constructed and operated in a specific orientation. Therefore, these terms should not be construed as a limitation to the embodiments of the present disclosure.

In addition, the terms such as “first” and “second” are only used for descriptive purposes, and should not be construed as indicating or implying relative importance or implying the number of indicated technical features. Thus, features limited by “first” and “second” may expressly or implicitly include at least one of that feature. In the description of the present disclosure, “a plurality of” means at least two, such as two or three, unless otherwise expressly and specifically defined. In the description of the present disclosure, “several” means at least one, such as one or two, unless otherwise expressly and specifically defined.

The CMP process is a typical global planarization process. Polycrystalline silicon is a hydrophobic material. When the polycrystalline silicon is subjected to CMP, the surface of the polycrystalline silicon needs to be activated using CMP slurry containing non-ionic surfactants, so as to reduce the roughness of the surface of the polycrystalline silicon, reduce the damage of the polycrystalline silicon in the CMP process, and obtain polycrystalline silicon with a relatively flat surface. After the CMP process, cleaning liquid containing surfactants needs to be used to clean and remove particles on the surface of the polycrystalline silicon, so as to reduce a contact angle of the surface of the polycrystalline silicon and increase a contact area between the surface of the polycrystalline silicon and deionized water in the cleaning liquid, that is, change the properties of the surface of the polycrystalline silicon from hydrophobicity to hydrophilicity, such that the deionized water in the cleaning liquid can remove particles from the surface of the polycrystalline silicon more excellently. Then, in the CMP process, due to the action of mechanical force, the surface of the polycrystalline silicon will be scratched, and particles generated in the CMP process will enter the scratches. After subsequent cleaning of the surface of the polycrystalline silicon with cleaning liquid, there are scratches on the surface of the thinned polycrystalline silicon, and there will be particle residuals in the scratches, thereby affecting the yield of the semiconductor structure.

The present disclosure provides CMP slurry, configured to thin a polycrystalline silicon structure, so as to obtain a polycrystalline silicon layer with a flat surface, and including: silicon dioxide abrasive particles, a peroxy compound, and deionized water. The peroxy compound has a volume percentage not less than 3% and not greater than 10%.

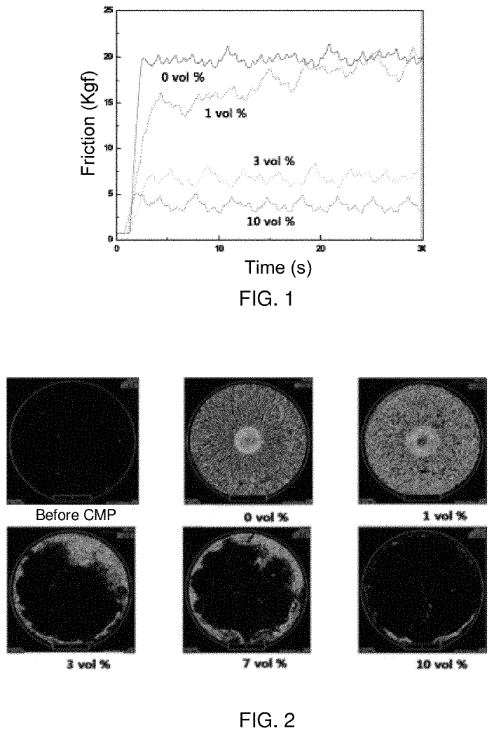

FIG. 1 is a schematic diagram of friction between CMP slurry and a polycrystalline silicon structure and a percentage of a peroxy compound in the CMP slurry in an embodiment. FIG. 2 is a schematic diagram of a surface of each polycrystalline silicon layer obtained by the CMP slurry with different percentages of the peroxy compound corresponding to FIG. 1. Specifically, the CMP slurry is used to polish and remove a polycrystalline silicon structure with a certain thickness to obtain a polycrystalline silicon layer with a smooth surface. Through performing CMP on the polycrystalline silicon structure using the CMP slurry in the present disclosure, uneven parts on the surface of the polycrystalline silicon and polycrystalline silicon exceeding a preset thickness are removed, and the preset thickness refers to a thickness of the polycrystalline silicon structure to be retained, that is, a thickness of a polycrystalline silicon layer to be obtained. In practical applications, the preset thickness can be set as required. The friction between the CMP slurry and the polycrystalline silicon structure is proportional to the number of scratches on the surface of the polycrystalline silicon structure. Greater friction between the CMP slurry and the polycrystalline silicon structure indicates a greater number of scratches on the surface of the polycrystalline silicon structure. The friction between the CMP slurry and the polycrystalline silicon structure can be reduced through the peroxy compound, thereby reducing the scratches on the surface of the polycrystalline silicon structure, avoiding particles remaining in the scratches, obtaining a polycrystalline silicon layer with less surface particles and scratches, and improving the yield of the semiconductor device with the polycrystalline silicon layer. FIG. 1 shows a relationship of the friction between the CMP slurry and the polycrystalline silicon structure with time when the peroxy compound in the CMP slurry has volume percentages of 0 vol %, 1 vol %, 3 vol %, and 10 vol % respectively. It can be seen from the figure that when the peroxy compound has a volume percentage greater than or equal to 3%, the friction between the CMP slurry and the polycrystalline silicon structure significantly decreases, and decreases with the increase of the percentage of the peroxy compound. FIG. 2 is a schematic diagram of a surface of a polycrystalline silicon layer (an overall schematic diagram of particles and scratches on the surface of the polycrystalline silicon layer) when the peroxy compound in the CMP slurry has volume percentages of 0 vol %, 1 vol %, 3 vol %, 7 vol %, and 10 vol % respectively before CMP. It can be seen from the figure that a higher volume percentage of the peroxy compound in the CMP slurry indicates less scratches and particles on the surface of the polycrystalline silicon layer and a more excellent polishing effect, such that the influence of the damage of the surface of the polycrystalline silicon layer on the yield of the semiconductor device is eliminated.

The above CMP slurry is configured to thin the polycrystalline silicon structure, so as to obtain the polycrystalline silicon layer with a flat surface, and the CMP slurry includes: the silicon dioxide abrasive particles, the peroxy compound, and the deionized water. The peroxy compound has a volume percentage not less than 3% and not greater than 10%. In a process of thinning the polycrystalline silicon structure by CMP, polycrystalline silicon in contact with the CMP slurry is oxidized into silicon dioxide by the peroxy compound, which reduces a contact angle of the CMP slurry, activates the surface of the polycrystalline silicon structure while removing a surfactant, improves a polishing effect and a cleaning effect after CMP, and reduces production costs. In addition, the peroxy compound can reduce friction between the CMP slurry and the polycrystalline silicon structure, thereby reducing scratches on a surface of the polycrystalline silicon structure.

In one of the embodiments, the peroxy compound may include but be not limited to hydrogen peroxide. For example, the peroxy compound is urea peroxide, performic acid, or peroxyacetic acid.

In one of the embodiments, the CMP slurry may include but be not limited to alkaline polishing slurry.

In one of the embodiments, the CMP slurry has a pH not less than 9 and not greater than 11.

In one of the embodiments, the CMP slurry further includes potassium hydroxide.

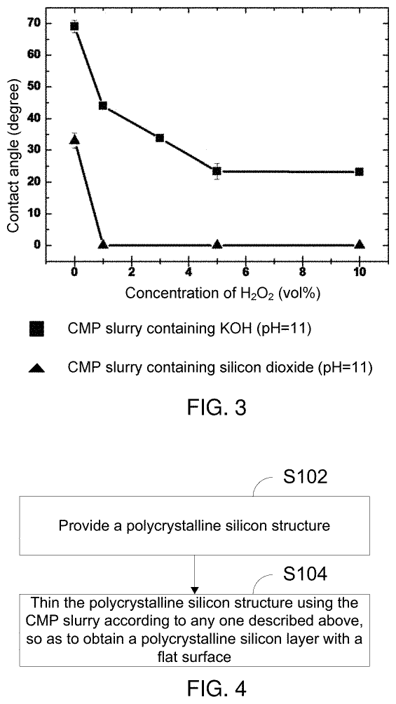

FIG. 3 is a schematic diagram illustrating variations of a contact angle of a polycrystalline silicon structure with a percentage of hydrogen peroxide in an embodiment. Exemplarily, the CMP slurry has a pH of 11. As shown in FIG. 3, in the CMP slurry containing silicon dioxide with a pH of 11 and the CMP slurry containing potassium hydroxide with a pH of 11, the contact angles between the CMP slurry and the surface of polycrystalline silicon both decrease first and then tend to be stable with the increase of the percentage of hydrogen peroxide, and the decrease in the contact angle can increase the contact area between the deionized water and the surface of polycrystalline silicon to improve the cleaning effect. After activation of the surface of polycrystalline silicon with typical surfactants, the contact angle is between 38 degrees and 49 degrees, and there are still several thousand particles on the surface of polycrystalline silicon after cleaning with a cleaning agent containing deionized water (such as DHF). Instead, after CMP is performed on the surface of polycrystalline silicon using the CMP slurry in the present disclosure, the surface of the polycrystalline silicon structure is oxidized into silicon dioxide which is a hydrophilic material, the contact angle is less than 5 degrees, there is no need to activate the surface of the polycrystalline silicon structure with a surfactant, the contact angle is less than that when the surfactant is used, and the cleaning effect of the deionized water on the surface is better. At this time, silicon dioxide and the particles can be removed cleanly with only the DHF cleaning agent, and a polycrystalline silicon layer with less surface defects is obtained.

In one of the embodiments, the silicon dioxide abrasive particles have a particle size greater than 0 nm and less than 150 nm, for example, 5 nm, 10 nm, 15 nm, 30 nm, 50 nm, 70 nm, 90 nm, 100 nm, 120 nm, and 130 nm.

In one of the embodiments, the silicon dioxide abrasive particles have a mass percentage not less than 5% and not greater than 10%, for example, 7%, 8%, and 9%. In practical applications, other abrasive particles can be selected to replace the silicon dioxide abrasive particles without reducing the mass of the polycrystalline silicon layer obtained after thinning.

The present disclosure further provides CMP equipment, using the CMP slurry according to any one described above for CMP.

In the above CMP equipment, the CMP slurry is configured to thin a polycrystalline silicon structure, so as to obtain a polycrystalline silicon layer with a flat surface, and the CMP slurry includes: silicon dioxide abrasive particles, a peroxy compound, and deionized water. The peroxy compound has a volume percentage not less than 3% and not greater than 10%. In a process of thinning the polycrystalline silicon structure by CMP, polycrystalline silicon in contact with the CMP slurry is oxidized into silicon dioxide by the peroxy compound, which reduces a contact angle of the polycrystalline silicon structure with the CMP slurry, activates the surface without a surfactant, improves a polishing effect and a cleaning effect after CMP, and reduces production costs. In addition, the peroxy compound can reduce friction between the CMP slurry and the polycrystalline silicon structure, thereby reducing scratches on a surface of the polycrystalline silicon structure, obtaining a polycrystalline silicon layer with less surface particles and scratches, and improving a yield of the semiconductor structure.

FIG. 4 is a schematic flowchart of a manufacturing method of a semiconductor structure in an embodiment. As shown in FIG. 4, the present disclosure further provides a manufacturing method of a semiconductor structure, including the following steps.

S102, a polycrystalline silicon structure is provided.

Specifically, a polycrystalline silicon structure requiring surface thinning is provided, that is, a polycrystalline silicon structure that requires overall thinning with a certain thickness is provided.

S104, the polycrystalline silicon structure is thinned using the CMP slurry according to any one described above, so as to obtain a polycrystalline silicon layer with a flat surface.

Specifically, the polycrystalline silicon structure is thinned using the CMP slurry according to any one described above. After uneven parts on the surface of the polycrystalline silicon are removed, a certain thickness of the polycrystalline silicon structure is removed as a whole to obtain a polycrystalline silicon layer composed of the remaining polycrystalline silicon structure. The thinning treatment is performed on the polycrystalline silicon structure as a whole. The polycrystalline silicon layer has a surface flatter than that of the polycrystalline silicon structure, and there are differences in the thickness direction.

In the above manufacturing method of the semiconductor structure, the polycrystalline silicon structure is thinned using the CMP slurry including the silicon dioxide abrasive particles, the peroxy compound, and the deionized water, so as to obtain a polycrystalline silicon layer with a flat surface. In the CMP slurry, the peroxy compound has a volume percentage not less than 3% and not greater than 10%. In a process of thinning the polycrystalline silicon structure by CMP, a polycrystalline silicon material in contact with the CMP slurry is oxidized into silicon dioxide by the peroxy compound, which reduces a contact angle of the polycrystalline silicon structure and the CMP slurry, activates the surface of the polycrystalline silicon structure while removing a surfactant, improves a cleaning effect, and reduces production costs. In addition, the peroxy compound can reduce friction between the CMP slurry and the polycrystalline silicon structure, thereby reducing scratches on a surface of the polycrystalline silicon structure, obtaining a polycrystalline silicon layer with less surface particles and scratches, and improving a yield of the semiconductor structure.

In one of the embodiments, the polycrystalline silicon structure includes a polycrystalline silicon base. At this time, the polycrystalline silicon layer obtained after thinning the polycrystalline silicon structure is the polycrystalline silicon base with a flat surface.

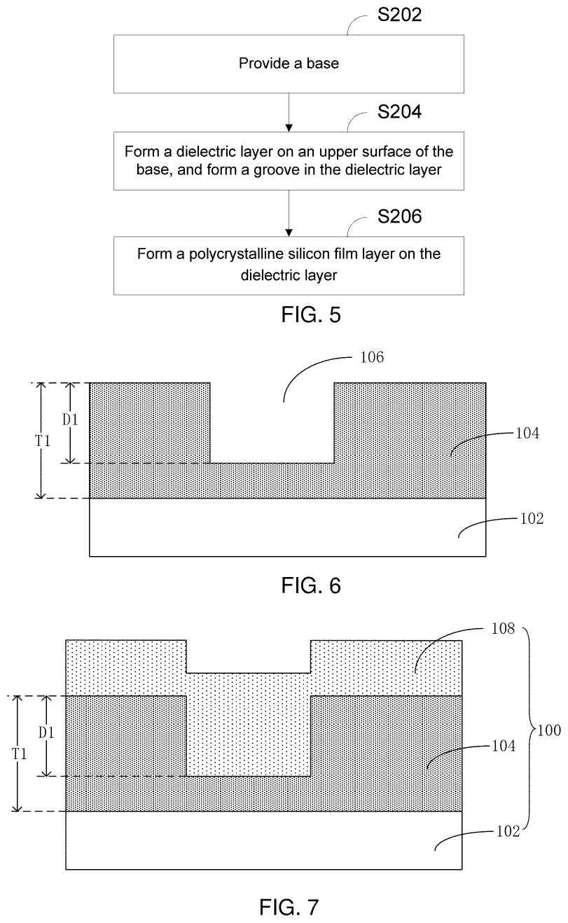

FIG. 5 is a schematic flowchart of providing a polycrystalline silicon structure in an embodiment. As shown in FIG. 5, a process of providing the polycrystalline silicon structure includes the following steps.

S202, a base is provided.

Specifically, the material of the base may be undoped monocrystalline silicon, monocrystalline silicon doped with impurities, silicon-on-insulator (SOI), stacked silicon-on-insulator (SSOI), stacked silicon-germanium-on-insulator (S-SiGeOI), silicon-germanium-on-insulator (SiGeOI) and germanium-on-insulator (GeOI), may also be a substrate with a device structure formed on the surface, the material of the substrate may be undoped monocrystalline silicon, monocrystalline silicon doped with impurities, SOI, SSOI, S-SiGeOI, SiGeOI and GeOI. As an example, in the present embodiment, monocrystalline silicon is selected as the constituent material of the base.

S204, a dielectric layer is formed on an upper surface of the base, and a groove is formed in the dielectric layer.

FIG. 6 is a schematic cross-sectional diagram of a semiconductor structure after a groove is formed in an embodiment. As shown in FIG. 6, specifically, firstly, a dielectric layer 104 is formed on the upper surface of the base 102 by a deposition process well known to those skilled in the art, such as a chemical vapor deposition (CVD) process and an atomic layer deposition (ALD) process. The upper surface refers to any surface of the base 102 which has a device structure or on which the device structure is subsequently formed. Secondly, a groove 106 is formed in the dielectric layer 104 by a photolithography etching process. In practical applications, the shape, depth, width, and length of the groove 106 can be set as required, exemplarily, the groove 106 is rectangular, and a depth D1 of the groove 106 is less than a thickness T1 of the dielectric layer 104.

In one of the embodiments, the dielectric layer 104 includes a nitride layer and an oxide layer. Exemplarily, the dielectric layer 104 includes at least one of a silicon nitride layer, a silicon dioxide layer, and a silicon oxynitride layer.

S206, a polycrystalline silicon film layer is formed on the dielectric layer.

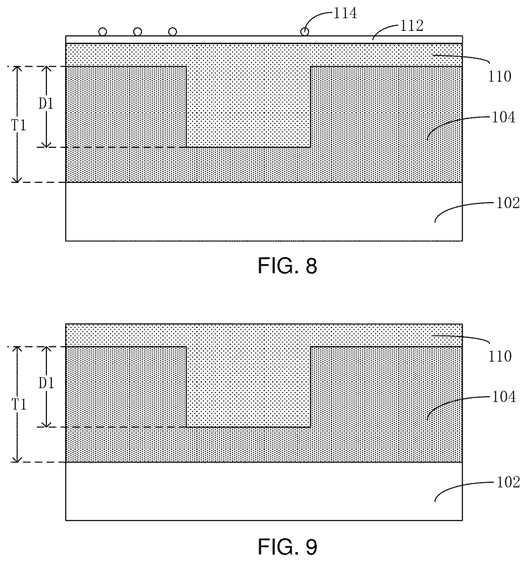

FIG. 7 is a schematic cross-sectional diagram of a semiconductor structure after a polycrystalline silicon film layer is formed in an embodiment. As shown in FIG. 7, a polycrystalline silicon film layer 108 is formed on an upper surface of the dielectric layer 104. The polycrystalline silicon film layer 108 covers the upper surface of the dielectric layer 104 and fill up the groove 106, so as to obtain a polycrystalline silicon structure 100 composed of the base 102, the dielectric layer 104, and the polycrystalline silicon film layer 108. An upper surface of the polycrystalline silicon layer is higher than the upper surface of the dielectric layer 104.

In one of the embodiments, after thinning the polycrystalline silicon structure 100, the method further includes: cleaning the thinned polycrystalline silicon structure 100 with DHF cleaning liquid. FIG. 8 is a schematic cross-sectional diagram of a semiconductor structure after thinning in an embodiment. FIG. 9 is a schematic cross-sectional diagram of a semiconductor structure after a polycrystalline silicon layer is formed in an embodiment. As shown in FIG. 8 and FIG. 9, after the polycrystalline silicon film layer 108 is formed, the polycrystalline silicon structure 100 is thinned using any one of the above CMP slurry, so as to obtain a polycrystalline silicon layer 110, a silicon dioxide layer 112 on the upper surface of the polycrystalline silicon, and particles 114 on an upper surface of the silicon dioxide layer 112. The silicon dioxide layer 112 is a thinner oxide layer obtained by oxidizing the polycrystalline silicon structure 100 with the peroxy compound in the CMP slurry in a thinning process. The particles 114 are generated in the thinning process. Then, the thinned polycrystalline silicon structure 100 is cleaned with the DHF cleaning liquid. Since the silicon dioxide layer 112 is a hydrophilic material, a contact angle of deionized water in the DHF cleaning liquid with the surface of the silicon dioxide layer 112 is small, and the particles 114 and the silicon dioxide layer 112 can be removed by the DHF cleaning liquid without using a surfactant to activate the thinned polycrystalline silicon structure 100. Then, the polycrystalline silicon layer 110 with a flat upper surface is obtained, and the upper surface of the polycrystalline silicon layer 110 is higher than the upper surface of the dielectric layer 104.

The present disclosure further provides a semiconductor structure, manufactured by the manufacturing method of a semiconductor structure according to any one described above.

In one of the embodiments, the semiconductor structure includes one of a CMOS device, a DRAM, and a MOSFET.

In the above semiconductor structure, a polycrystalline silicon structure is thinned using CMP slurry including silicon dioxide abrasive particles, a peroxy compound, and deionized water, so as to obtain a polycrystalline silicon layer with a flat surface. The peroxy compound in the CMP slurry has a volume percentage not less than 3% and not greater than 10%. In a process of thinning the polycrystalline silicon structure by CMP, polycrystalline silicon in contact with the CMP slurry is oxidized into silicon dioxide by the peroxy compound, which reduces a contact angle of the polycrystalline silicon structure with the CMP slurry, activates the surface of the polycrystalline silicon structure while removing a surfactant, improves a polishing effect and a cleaning effect after CMP, and reduces production costs. In addition, the peroxy compound can reduce friction between the CMP slurry and the polycrystalline silicon structure, thereby reducing scratches on a surface of the polycrystalline silicon structure, obtaining a polycrystalline silicon layer with less surface particles and scratches, and improving a yield of the semiconductor structure.

It should be understood that although steps in the flowcharts of FIG. 4 and FIG. 5 are sequentially displayed according to the arrows, the steps are not necessarily executed in the order indicated by the arrows. The execution order of the steps is not strictly limited, and the steps may be executed in other orders, unless clearly described otherwise. Moreover, at least some of the steps in FIG. 4 and FIG. 5 may include a plurality of sub-steps or stages. The sub-steps or stages are not necessarily executed at the same time, but may be executed at different times. The execution order of the sub-steps or stages is not necessarily carried out sequentially, but may be executed alternately with other steps or at least some of the sub-steps or stages of other steps.

The technical features of the above embodiments can be employed in arbitrary combinations. To provide a concise description, all possible combinations of all technical features of the above embodiments may not be described; however, these combinations of technical features should be construed as disclosed in the description as long as no contradiction occurs.

Only several embodiments of the present disclosure are described in detail above, but they should not therefore be construed as limiting the scope of the present disclosure. It should be noted that those of ordinary skill in the art can further make several variations and improvements without departing from the conception of the embodiments of the present disclosure. These variations and improvements all fall within the protection scope of the embodiments of the present disclosure. Therefore, the protection scope of the embodiments of the present disclosure should be subject to the protection scope defined by the claims.

1. A chemical mechanical polishing (CMP) slurry, configured to thin a polycrystalline silicon structure, so as to obtain a polycrystalline silicon layer with a flat surface, and comprising: silicon dioxide abrasive particles, a peroxy compound, and deionized water, wherein
the peroxy compound has a volume percentage not less than 3% and not greater than 10%.

2. The CMP slurry according to claim 1, wherein the peroxy compound comprises hydrogen peroxide.

3. The CMP slurry according to claim 1, wherein the CMP slurry is alkaline polishing slurry.

4. The CMP slurry according to claim 3, wherein the CMP slurry has a pH not less than 9 and not greater than 11.

5. The CMP slurry according to claim 3, the CMP slurry further comprises potassium hydroxide.

6. The CMP slurry according to claim 1, wherein the silicon dioxide abrasive particles have a particle size greater than 0 nm and less than 150 nm.

7. The CMP slurry according to claim 1, wherein the silicon dioxide abrasive particles have a mass percentage not less than 5% and not greater than 10%.

8. CMP equipment, using the CMP slurry according to claim 1 for CMP.

9. A manufacturing method of a semiconductor structure, comprising:
providing a polycrystalline silicon structure; and
thinning the polycrystalline silicon structure using the CMP slurry according to claim 1, so as to obtain a polycrystalline silicon layer with a flat surface.

10. The manufacturing method according to claim 9, wherein the polycrystalline silicon structure comprises a polycrystalline silicon base.

11. The manufacturing method according to claim 9, wherein the providing a polycrystalline silicon structure comprises:
providing a base;
forming a dielectric layer on an upper surface of the base, and forming a groove in the dielectric layer; and
forming a polycrystalline silicon film layer on an upper surface of the dielectric layer, wherein the polycrystalline silicon film layer covers the upper surface of the dielectric layer and fills up the groove,
wherein an upper surface of the polycrystalline silicon layer is higher than the upper surface of the dielectric layer.

12. The manufacturing method according to claim 11, wherein the dielectric layer comprises a nitride layer and an oxide layer.

13. The manufacturing method according to claim 9, wherein after thinning the polycrystalline silicon structure, the manufacturing method further comprises:
cleaning the thinned polycrystalline silicon structure with diluted hydrofluoric acid (DHF) cleaning liquid.

14. A semiconductor structure, manufactured by the manufacturing method of a semiconductor structure according to claim 9.

15. The semiconductor structure according to claim 14, comprising one of a complementary metal oxide semiconductor (CMOS) device, a dynamic random access memory (DRAM), or a metal oxide semiconductor field-effect transistor (MOSFET).
